(19) United States
(12) Patent Application Publication
(10) Pub. No.: US 2025/0253222 A1
(43) Pub. Date: Aug. 7, 2025

(54) SEMICONDUCTOR DEVICE

(71) Applicant: Taiwan Semiconductor Manufacturing Company, Ltd., Hsinchu (TW)

(72) Inventors: Kuan-Yu Chen, Hsinchu City (TW); Hsuan-Cheng Kuo, Hsinchu County (TW); Wan-Yu Lee, Taipei City (TW); Wei-Cheng Wu, Hsinchu City (TW); Hua-Wei Tseng, New Taipei City (TW); Ta-Hsuan Lin, Hsinchu City (TW); Chih-Chiang Chang, New Taipei City (TW)

(73) Assignee: Taiwan Semiconductor Manufacturing Company, Ltd., Hsinchu (TW)

(21) Appl. No.: 18/430,507

(22) Filed: Feb. 1, 2024

(51) Int. Cl. H01L 23/498; H01L 23/00; H01L 23/48; H01L 25/065

(52) U.S. Cl. CPC H01L 23/49822; H01L 23/481; H01L 23/49816; H01L 23/49838; H01L 24/16; H01L 24/32; H01L 24/73; H01L 25/0652; H01L 2224/16227; H01L 2224/16238; H01L 2224/32225; H01L 2224/73204; H01L 2924/181

(57) ABSTRACT

A semiconductor device includes a first integrated circuit, a bridge die, and a redistribution layer (RDL) structure. The first integrated circuit includes a first interconnect structure, a first passivation layer and a first conductive connector electrically connected to the first interconnect structure and disposed on the first passivation layer. The bridge die bridge die includes a second interconnect structure, a second passivation layer and a second conductive connector electrically connected to the second interconnect structure. The RDL structure is disposed between and electrically connected to the first integrated circuit and the bridge die, wherein the first passivation layer is in direct contact with the first conductive connector, the first conductive connector is in direct contact with the RDL structure, and the first passivation layer is a single layer and includes a first inorganic material.

### BACKGROUND

In recent years, the semiconductor industry has experienced rapid growth due to continuous improvement in integration density of various electronic components, e.g., transistors, diodes, resistors, capacitors, etc. For the most part, this improvement in integration density has come from successive reductions in minimum feature size, which allows more components to be integrated into a given area.

These smaller electronic components also require smaller packages that occupy less area than previous packages. Examples of the type of packages for semiconductors include quad flat pack (QFP), pin grid array (PGA), ball grid array (BGA), flip chips (FC), three-dimensional integrated circuits (3DICs), wafer level packages (WLPs), and package on package (POP) devices. Some 3DICs are prepared by placing chips over chips on a semiconductor wafer level. The 3DICs provide improved integration density and other advantages, such as faster speeds and higher bandwidth, because of the decreased length of interconnects between the stacked chips. However, there are many challenges related to 3DICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1E are schematic cross-sectional views illustrating a method of manufacturing a semiconductor device according to some embodiments of the disclosure.

FIG. 2A is a partial enlarged view of a region R of FIG. 1E, and FIG. 2B is a top view of FIG. 2A.

FIG. 3A is a schematic cross-sectional view of a semiconductor device according to some embodiments of the disclosure, and FIG. 3B is a partial enlarged view of a region R of FIG. 3A.

FIG. 4A is a schematic cross-sectional view of a semiconductor device according to some embodiments of the disclosure, and FIG. 4B is a partial enlarged view of a region R of FIG. 4A.

FIG. 5A is a schematic cross-sectional view of a semiconductor device according to some embodiments of the disclosure, and FIG. 5B is a partial enlarged view of a region R of FIG. 5A.

FIG. 6A is a partial enlarged schematic cross-sectional view of a semiconductor device according to some embodiments of the disclosure, and FIG. 6B is a top view of FIG. 6A.

FIG. 7A is a partial enlarged schematic cross-sectional view of a semiconductor device according to some embodiments of the disclosure, and FIG. 7B is a top view of FIG. 7A.

FIG. 8 is a schematic cross-sectional view of a semiconductor device according to some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

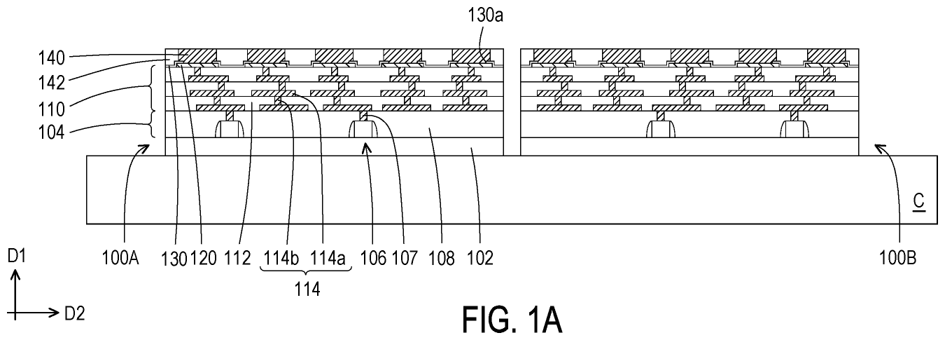

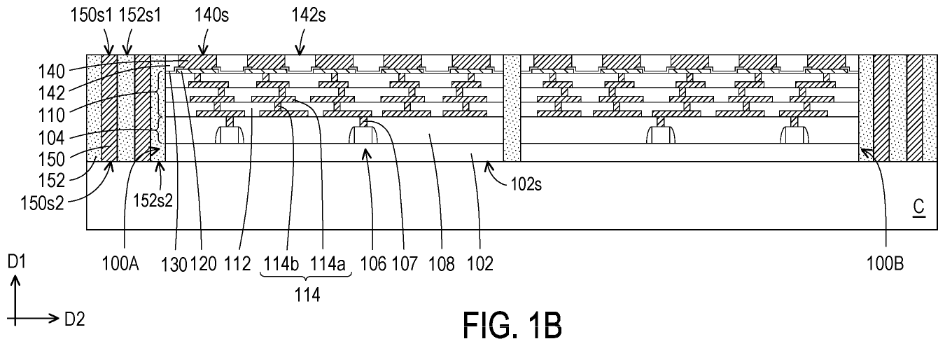

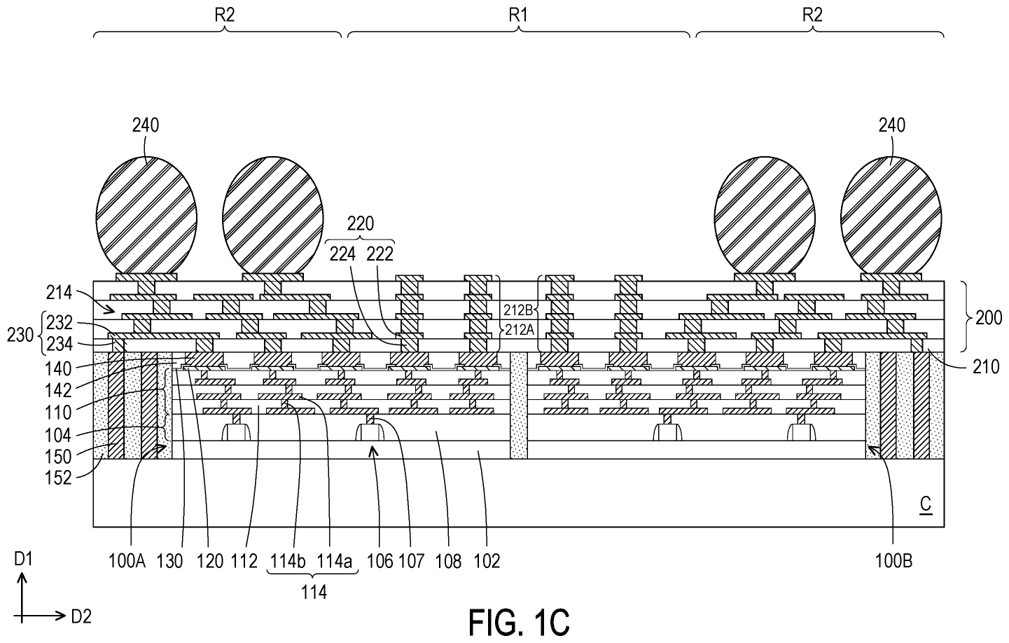

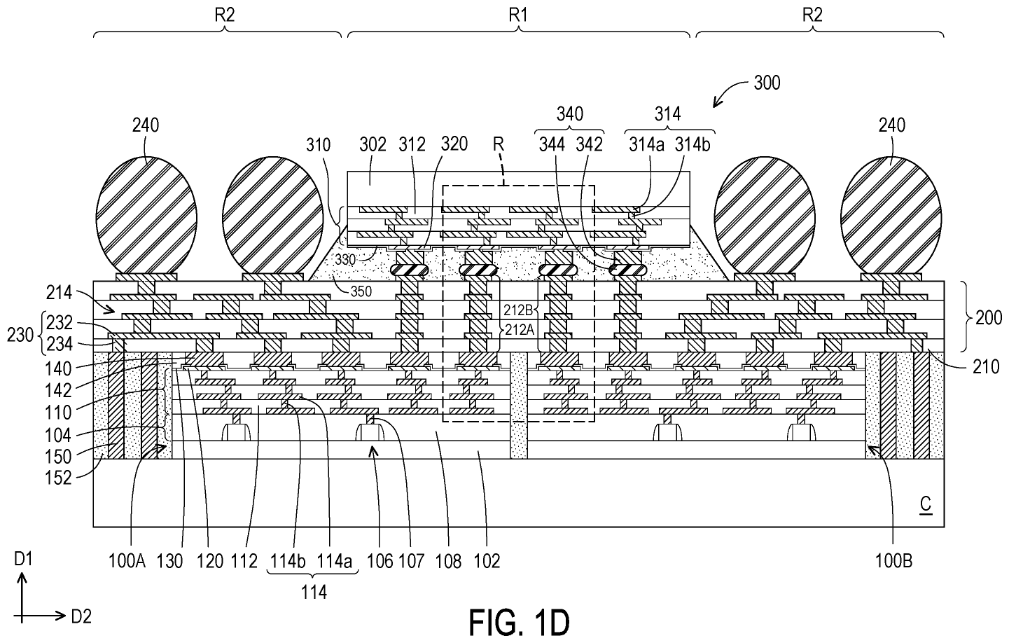

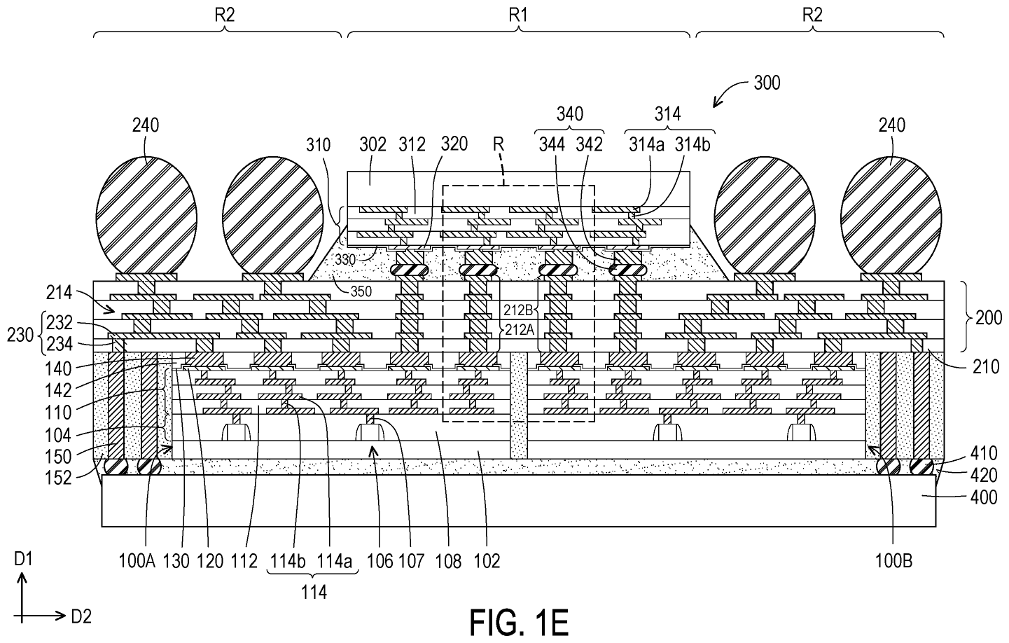

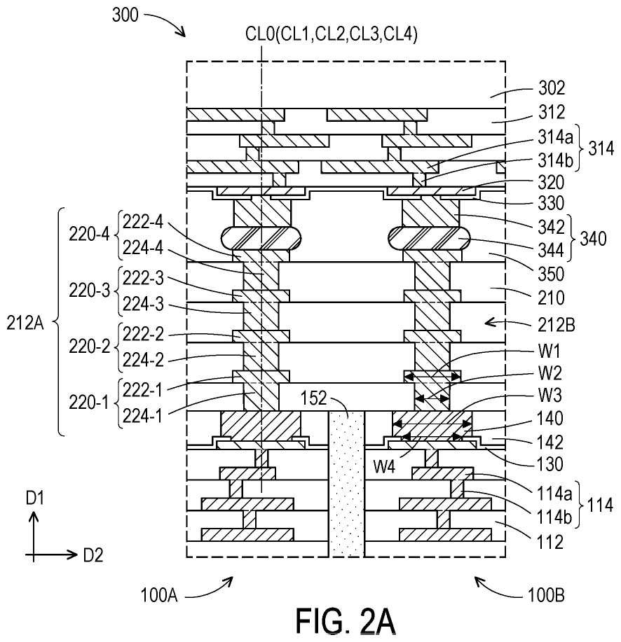

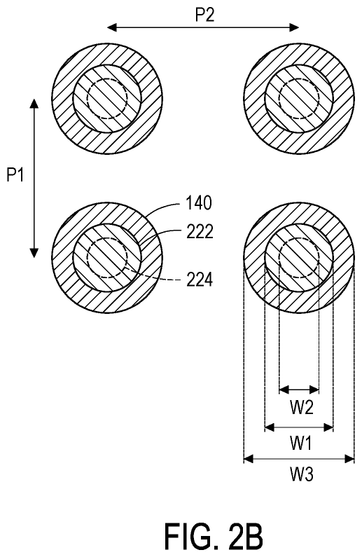

FIG. 1A to FIG. 1E are schematic cross-sectional views illustrating a method of manufacturing a semiconductor device according to some embodiments of the disclosure, FIG. 2A is a partial enlarged view of a region R of FIG. 1E, and FIG. 2B is a top view of FIG. 2A.

Referring to FIG. 1A, a plurality of integrated circuits 100A, 100B are formed over a carrier C. The carrier C is used as a platform or a support for a packaging process described below. In some embodiments, the carrier C includes a semiconductor material (such as silicon, or the like), a dielectric material (such as glass, a ceramic material, quartz, or the like), the like, or a combination thereof. In some embodiments, the integrated circuits 100A, 100B are picked and placed side by side. The integrated circuits 100A, 100B may be of the same type or different types. For example, the integrated circuit 100A, 100B may be a logic die (e.g., system-on-a-chip (SoC), central processing unit (CPU), graphics processing unit (GPU), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), a multi-functional die, the like, or a combination thereof. In some embodiments, the integrated circuits 100A, 100B are both SoC dies. The integrated circuits 100A, 100B have similar structures. In some embodiments, dimensions such as widths, lengths and heights of the integrated circuits 100A, 100B are substantially the same. In alternative embodiments, widths, lengths and/or heights of the integrated circuits 100A, 100B are different.

In some embodiments, the integrated circuit 100A, 100B includes a substrate 102, a device layer 104 in and/or on the substrate 102, an interconnect structure 110 over the device layer 104, a plurality of conductive pads 120, a passivation layer 130 and a plurality of conductive connectors 140. In some embodiments, the substrate 102 is a glass substrate, a ceramic substrate, a semiconductor substrate, or the like. In some embodiments, the substrate 102 is a silicon wafer or an active layer of a semiconductor-on-insulator (SOI) substrate, or the like. The substrate 102 may include a semiconductor material, such as doped or undoped silicon, or may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or a combination thereof. Other substrates, such as multi-layered or gradient substrates, may also be used. The device layer 104 may be disposed on a top surface of the substrate 102 or partially disposed in the substrate 102. The device layer 104 includes at least one device 106 in a dielectric layer 108, for example. The device 106 may be an active device such as a transistor. The device 106 is electrically connected to the interconnect structure 110 through a via 107.

The interconnect structure 110 is disposed over the device layer 104, for example. The interconnect structure 110 may include a plurality of dielectric layers 112 and a plurality of conductive patterns 114 in the dielectric layers 112. A material of the dielectric layer 112 may include an extremely low-k (ELK) dielectric material having a dielectric constant of about 2.1 or less, and the extremely low-k dielectrics are generally low-k dielectrics formed into a porous structure. Porosity reduces the effective dielectric constant. The dielectric layer 112 may be formed any acceptable deposition process, such as spin coating, CVD, laminating, the like, or a combination thereof. In alternative embodiments, the dielectric layer 112 may include a low-k dielectric material, an oxide such as silicon oxide, phosphosilicate glass (PSG), borosilicate glass (BSG), boron-doped phosphosilicate glass (BPSG), a nitride such as silicon nitride, or the like.

The conductive patterns 114 may be conductive lines 114a and/or conductive vias 114b. The conductive vias 114b may extend through the dielectric layers 112 to provide vertical connections between layers of conductive lines 114a. The conductive pattern 114 may include copper, silver, gold, tungsten, aluminum, copper doped with aluminum or manganese, a combination thereof, or the like. In alternative embodiments, the conductive pattern 114 further includes an optional diffusion barrier layer and/or optional adhesion layer. A material of the diffusion barrier layer may include titanium, titanium nitride, titanium oxide, tantalum, tantalum nitride, titanium oxide, or other alternatives, and suitable materials for the conductive material.

The conductive patterns 114 may be formed by using a damascene process, including forming a dielectric material, forming a plurality of openings corresponding to the desired patterns of the conductive lines and the conductive vias, filling the openings with a conductive material and removing excess of the conductive material outside the openings. In some embodiments, the conductive patterns 114 are formed by a dual damascene process, and the conductive lines 114a and the respective conductive vias 114b are formed integrally. In alternative embodiments, the conductive patterns 114 are formed by a single damascene process or other suitable process, and the conductive lines 114a and the conductive vias 114b are formed separately. In some embodiments, the interconnect structure 110 may include six layers of conductive lines 114a and conductive vias 114b and three layers of dielectric layers 112. In alternative embodiments, the interconnect structure 110 include a different number of layers of conductive patterns 114 and a different number of layers of dielectric layers 112.

In some embodiments, the conductive pads 120 are disposed on an outermost surface of the interconnect structure 110. The conductive pads 120 may be aluminum pads or other suitable conductive pads. The conductive pads 120 are electrically connected to the interconnect structure 110. For example, the conductive pads 120 are respectively disposed on the conductive vias 114b of the interconnect structure 110. In some embodiments, the passivation layer 130 is disposed over the conductive pads 120 and has a plurality of openings 130a to expose portions of the conductive pads 120. The passivation layer 130 may include an inorganic material, and the passivation layer 130 is an inorganic layer. In some embodiments, the passivation layer 130 includes an oxide such as silicon oxide, a nitride such as silicon nitride, or the like. The passivation layer 130 may be formed any acceptable deposition process, such as CVD, PVD, spin coating, laminating, the like, or a combination thereof. The passivation layer 130 may be conformal to the conductive pads 120. A thickness of the passivation layer 130 may be in a range of 0.4 μm to 1.8 μm. For example, the passivation layer 130 of silicon oxide has a thickness in a range of 1.4 μm to 1.8 μm, and the passivation layer 130 of silicon nitride has a thickness in a range of 0.4 μm to 0.8 μm. The conductive pad 120 may have a critical dimension ranging from 5 μm to 20 μm. The opening 130a may have a critical dimension ranging from 2 μm to 15 μm. However, the disclosure is not limited thereto. However, the disclosure is not limited thereto.

In some embodiments, the conductive connectors 140 are formed on and electrically connected to the conductive pads 120 through the openings 130a respectively. The conductive connectors 140 may be disposed in the openings 130a and on the passivation layer 130. The conductive connectors 140 are also referred to as conductive terminals. In some embodiments, the conductive connectors 140 includes conductive pillars. The conductive connector 140 may be T-shaped. For example, the conductive connector 140 has a bottom portion in the opening 130a of the passivation layer 130 and a top portion on the passivation layer 130. The top portion may be physically connected to the bottom portion and has a larger width than the bottom portion. The bottom portion and the top portion of conductive connector 140 may have substantially vertical sidewalls. In some embodiments, the conductive connectors 140 may include a conductive material such as solder, copper, aluminum, gold, nickel, silver, palladium, tin, the like, or a combination thereof. In alternative embodiments, the conductive connectors 140 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 140 may be formed by a suitable process such as evaporation, plating, ball drop, screen printing, or a ball mounting process. In alternative embodiments, a diffusion barrier layer (not shown) is disposed under a bottom surface of the conductive connector 140. A material of the diffusion barrier layer may include titanium, titanium nitride, titanium oxide, tantalum, tantalum nitride, titanium oxide, or other alternatives. In some embodiments, the conductive connectors 140 are arranged along a periphery of the integrated circuit 100A, 100B. For example, the conductive connectors 140 are disposed at four sides of the integrated circuit 100A, 100B. In alternative embodiments, the conductive connectors 140 are disposed at opposite sides of the integrated circuit 100A, 100B.

In some embodiments, a dielectric layer 142 is formed over the passivation layer 130 to surround the conductive connectors 140. The hardness of the passivation layer 130 may be larger than the hardness of the dielectric layer 142. That is, the passivation layer 130 is harder than the dielectric layer 142. For example, the hardness of the passivation layer 130 is in a range of 10 Gpa to 100 Gpa, and the hardness of the dielectric layer 142 is in a range of 0.1 Gpa to 0.3 Gpa. The dielectric layer 142 may include an organic material such as polyimide, polybenzoxazole (PBO), benzocyclobutene (BCB), or the like. The dielectric layer 142 may include a material having a glass transition temperature (Tg) higher than 200° C. The dielectric layer 142 may be formed by any acceptable deposition process, such as spin coating, CVD, laminating, the like, or a combination thereof. In some embodiments, the passivation layer 130 is a single layer and is in direct contact with the conductive pad 120, the conductive connector 140 and the dielectric layer 142. In some embodiments, the passivation layer 130 is further in direct contact with the interconnect structure 110. For example, the passivation layer 130 is in direct contact with the dielectric layer 112 (e.g., ELK dielectric layer) of the interconnect structure 110.

Referring to FIG. 1B, a plurality of through vias 150 are formed over the carrier C to surround the integrated circuits 100A, 100B, and an encapsulant 152 is formed to encapsulate the integrated circuits 100A, 100B and the through vias 150. In some embodiments, the through vias 150 are also referred to as through integrated fan-out vias (TIVs). In some embodiments, sidewalls of the integrated circuits 100A, 100B and the through vias 150 are encapsulated by the encapsulant 152. In some embodiments, the encapsulant 152 includes a molding compound, a molding underfill, a resin such as epoxy, a combination thereof, or the like. In alternative embodiments, the encapsulant 152 includes a photo-sensitive material such as polybenzoxazole (PBO), polyimide, benzocyclobutene (BCB), a combination thereof, or the like, which may be easily patterned by exposure and development processes or laser drilling process. In alternative embodiments, the encapsulant 152 includes nitride such as silicon nitride, oxide such as silicon oxide, phosphosilicate glass (PSG), borosilicate glass (BSG), boron-doped phosphosilicate glass (BPSG), a combination thereof, or the like. In some embodiments, the encapsulant 152 is formed by forming an encapsulant material by a suitable fabrication technique such as spin-coating, lamination, deposition, or similar processes. The encapsulant material encapsulates top surfaces and sidewalls of the integrated circuits 100A, 100B and the through vias 150 and fills the gap between the integrated circuits 100A, 100B and the through vias 150. Thereafter, a grinding or polishing process is performed to remove a portion of the encapsulant material, such that the top surfaces of the integrated circuits 100A, 100B and the through vias 150 are exposed. In some embodiments, the surfaces 140s, 142s (e.g., top surfaces) of the conductive connectors 140 and the dielectric layers 142 of the integrated circuits 100A, 100B and the surfaces 150s1 (e.g., top surfaces) of the through vias 150 are substantially coplanar with the surface 152s1 (e.g., top surface) of the encapsulant 152. The surfaces 102s (e.g., bottom surfaces) of the substrates 102 of the integrated circuits 100A, 100B and the surfaces 150s2 (e.g., bottom surfaces) of the through vias 150 may be substantially coplanar with the surface 152s2 (e.g., bottom surface) of the encapsulant 152.

Referring to FIG. 1C, a redistribution layer (RDL) structure 200 is formed over the integrated circuits 100A, 100B and the encapsulant 152. The RDL structure 200 includes a plurality of dielectric layers 210 and routing structures 212A, 212B and 214 in the dielectric layers 210. The routing structures 212A, 212B and 214 respectively include a plurality of conductive patterns 220, 230. The dielectric layer 210 may include an organic material such as polyimide, polybenzoxazole (PBO), benzocyclobutene (BCB), or the like. The dielectric layer 210 may be formed by any acceptable deposition process, such as spin coating, CVD, laminating, the like, or a combination thereof. The dielectric layer 210 may include a material having a glass transition temperature (Tg) higher than 200° C. For example, the dielectric layer 210 and the dielectric layer 142 are both high Tg polyimide. The hardness of the passivation layer 130 may be larger than the hardness of the dielectric layers 210. That is, the passivation layer 130 is harder than the dielectric layers 210. In some embodiments, the materials of the dielectric layers 210 and the dielectric layer 142 are both organic materials. The materials of the dielectric layers 210 and the dielectric layer 142 may be the same. For example, the materials of the dielectric layers 210 and the dielectric layer 142 are both polyimide.

The conductive patterns 220 (e.g., 220-1, 220-2, 220-3, 220-4) of the routing structure 212A, 212B may include a plurality of conductive pads 222 (e.g., 222-1, 222-2, 222-3, 222-4) and a plurality of conductive vias 224 (e.g., 224-1, 224-2, 224-3, 224-4) stacked alternately. The conductive patterns 230 of the routing structures 214 may include a plurality of conductive lines 232 and a plurality of conductive vias 234 stacked alternately. The conductive vias 224 may extend through the dielectric layers 210 to provide vertical connections between conductive pads 222. Similarly, the conductive vias 234 may extend through the dielectric layers 210 to provide vertical connections between layers of conductive lines 232. For example, a first surface (e.g., top surface) of the conductive via 224 is substantially coplanar with a first surface (e.g., top surface) of the respective dielectric layer 210. A second surface (e.g., bottom surface) opposite to the first surface of the conductive via 224 is substantially coplanar with a second surface (e.g., top surface) of the respective dielectric layer 210 and the respective conductive via 224. The conductive pattern 220, 230 may include copper, silver, gold, tungsten, aluminum, copper doped with aluminum or manganese, a combination thereof, or the like. In alternative embodiments, the conductive pattern 220, 230 further includes an optional diffusion barrier layer and/or optional adhesion layer. A material of the diffusion barrier layer may include titanium, titanium nitride, titanium oxide, tantalum, tantalum nitride, titanium oxide, or other alternatives, and suitable materials for the conductive material. The conductive patterns 220, 230 may be formed by using a damascene process, including forming a dielectric material, forming a plurality of openings corresponding to the desired patterns of the conductive lines and the conductive vias, filling the openings with a conductive material and removing excess of the conductive material outside the openings. The conductive pattern 220, 230 may be formed simultaneously or separately. In some embodiments, the conductive patterns 220, 230 are formed by a dual damascene process, the conductive pads 222 and the respective conductive vias 224 are formed integrally, and the conductive lines 232 and the respective conductive vias 234 are formed integrally. For example, an interface does not exist between the conductive pad 222 and the respective conductive via 224 and between the conductive line 232 and the respective conductive via 234. In alternative embodiments, the conductive patterns 220, 230 are formed by a single damascene process or other suitable process. In such embodiments, the conductive pads 222 and the respective conductive vias 224 are formed separately, and the conductive lines 232 and the respective conductive vias 234 are formed separately. In such embodiments, an interface exists between the conductive pad 222 and the respective conductive via 224 and between the conductive line 232 and the respective conductive via 234. In some embodiments, the RDL structure 200 may include four layers of conductive patterns 220, 230 and four layers of dielectric layers 210. In alternative embodiments, the RDL structure 200 include a different number of layers of conductive patterns 220, 230 and a different number of layers of dielectric layers 210. In some embodiments, the RDL structure 200 is also referred to as an integrated fan-out (InFO) structure.

In some embodiments, the routing structures 212A, 212B are used to provide the shortest path between the integrated circuit 100A, 100B and the bridge die 300 (shown in FIG. 1D). For example, the routing structures 212A, 212B are disposed at a first region R1 of the RDL structure 200. The first region R1 is a region between the integrated circuits 100A, 100B and may be also referred to as a die to die region. In some embodiments, the first region R1 is overlapped with the bridge die 300 along a first direction D1. The first direction D1 is a stacking direction of the integrated circuit 100A, 100B, the RDL structure 200 and the bridge die 300. For example, the routing structures 212A, 212B is disposed directly below (or above) the bridge die 300. A second direction D2 is substantially perpendicular to the first direction D1, for example. In some embodiments, the first direction D1 is a vertical direction such as z direction, and the second direction is a horizontal direction such as x direction.

Referring to FIGS. 1C, 2A and 2B, in some embodiments, the conductive patterns 220 (e.g., 220-1, 220-2, 220-3, 220-4) of the routing structure 212A, 212B are stacked and overlapped with one another along the first direction D1. The routing structure 212A, 212B may be also referred to as a stacked via routing. The stacked via routing is suitable for finer pitch P1, P2 (shown in FIG. 2B) such as smaller than 16 μm since it occupies a smaller footprint. The conductive patterns 220 may respectively include a plurality of conductive pads 222-1, 222-2, 222-3, 222-4 and a plurality of conductive vias 224-1, 224-2, 224-3, 224-4 stacked alternately. The conductive vias 224-1, 224-2, 224-3, 224-4 are respectively disposed between adjacent two of the conductive connector 140 and the conductive pads 222-1, 222-2, 222-3, 222-4. In some embodiments, the outermost (e.g., topmost) conductive pad 222-4 is a UBM (under-bump metallization), and the outermost (e.g., bottommost) conductive via 224-1 is in direct contact with the conductive connector 140 in the passivation layer 130 and the dielectric layer 142.

The width W1 of the conductive pad 222-1, 222-2, 222-3, 222-4 is larger than the widths W2 of the conductive vias 224-1, 224-2, 224-3, 224-4. In some embodiments, a width W1 of the conductive pads 222-1, 222-2, 222-3, 222-4 is substantially the same, and a width W2 of the conductive vias 224-1, 224-2, 224-3, 224-4 is substantially the same. However, the disclosure is not limited thereto. The conductive pads 222-1, 222-2, 222-3, 222-4 may have different width, and/or the conductive vias 224-1, 224-2, 224-3, 224-4 may have different width. For example, the width of the bottommost conductive via 224-1 is smaller than the width of other conductive vias 224-2, 224-3, 224-4 stacked thereover. In some embodiments, the width W1 of the conductive pads 222-1, 222-2, 222-3, 222-4 is smaller than the width W3 of the conductive connector 140 (e.g., top portion of the conductive connector 140) on the passivation layer 130, and the width W2 of the conductive vias 224-1, 224-2, 224-3, 224-4 is smaller than the width W4 of the conductive connector 140 (e.g., bottom portion of the conductive connector 140) in the passivation layer 130. A pitch P1 ranges from 20 μm to 30 μm, and a pitch P2 ranges from 15 μm to 25 μm, for example. In some embodiments, the pitch P1 is a distance between the center lines CL0 of the adjacent conductive connectors 140 and between the center lines CL1, CL2, CL3, CL4 of the adjacent conductive patterns 220 along the first direction D1, and the pitch P2 is a distance between the center lines CL0 of the adjacent conductive connectors 140 and between the center lines CL1, CL2, CL3, CL4 of the adjacent conductive patterns 220 along the second direction D2. It is noted that two routing structures 212A and two routing structures 212B are illustrated, however, there may be one or more than two routing structures 212A and/or one or more than two routing structures 212B. Similarly, four conductive patterns 220 are illustrated in each routing structure 212A, 212B, and there may be less or more conductive patterns 220 in each routing structure 212A, 212B.

In some embodiments, as shown in FIG. 2A, the center lines CL1-CL4 of the conductive patterns 220-1, 220-2, 220-3, 220-4 are substantially aligned with one another. The center lines CL1-CL4 of the conductive patterns 220-1, 220-2, 220-3, 220-4 may be further aligned with the center line CL0 of the conductive connector 140 of the integrated circuit 100A, 100B. For example, as shown in FIG. 2B, the conductive patterns 220-1, 220-2, 220-3, 220-4 and the conductive connector 140 are concentric. In such embodiments, a horizontal distance (along the second direction D2) between the conductive patterns 220-1, 220-2, 220-3, 220-4 and the conductive connector 140 is substantially the same as a vertical distance (along the first direction D1) between the conductive patterns 220-1, 220-2, 220-3, 220-4 and the conductive connector 140 increases. The horizontal distance may be a horizontal distance between the center line CL1-CL4 of the conductive pattern 220-1, 220-2, 220-3, 220-4 and the center line CL0 of the conductive connector 140. In some embodiments, the horizontal distance is about zero since the center lines CL0-CL4 are substantially aligned with one another.

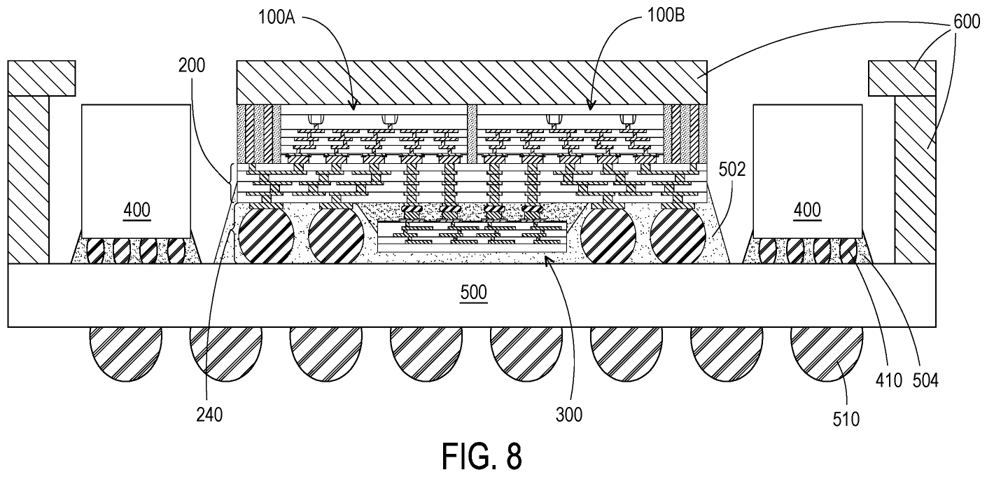

In some embodiments, the routing structures 214 are used to provide the conductive path between the integrated circuits 100A, 100B and/or other integrated circuit (such as integrated circuit 400 (shown in FIGS. 1E and 8)). For example, the routing structures 214 are disposed in a second region R2 aside the first region R1 of the RDL structure 200. The second region R2 may be separated from the bridge die 300 along the first direction D1. The second region R2 surrounds the first region R1, for example.

In some embodiments, the RDL structure 200 is directly formed over the integrated circuits 100A, 100B and the encapsulant 152. For example, the bottommost dielectric layer 210 is in direct contact with the dielectric layer 142 and the encapsulant 152. The bottommost conductive patterns 220, 230 may be directly and respectively formed on the conductive connectors 140 and the through vias 150, to electrically connect the RDL structure 200 and the integrated circuits 100A, 100B and the through vias 150.

Referring to FIG. 1D, the bridge die 300 is bonded to the RDL structure 200, to electrically connect the integrated circuits 100A, 100B. The bridge die 300 is flip chip bonded to the RDL structure 200, for example. In some embodiments, the bridge die 300 includes a substrate 302, an interconnect structure 310, a plurality of conductive pads 320, a passivation layer 330 and a plurality of conductive connectors 340. The substrate 302 may be similar to the substrate 102. The bridge die 300 may be free of active devices. For example, the bridge die 300 is free of transistors, diodes, and/or the like. Further, the bridge die 300 may be also be free of passive devices such as capacitors, resistors, inductors, and/or the like. The interconnect structure 310 is disposed over the substrate 302, for example. The interconnect structure 310 may include a plurality of dielectric layers 312 and a plurality of conductive patterns 314 in the dielectric layers 312. A material of the dielectric layers 312 may be a low-k dielectric material, an oxide such as silicon oxide, phosphosilicate glass (PSG), borosilicate glass (BSG), boron-doped phosphosilicate glass (BPSG), a nitride such as silicon nitride, or the like. The low-k dielectric material has a smaller dielectric constant than silicon oxide, and examples of low-k dielectric material include organosilicate glasses (OSG) such as carbon-doped silicon dioxide and fluorine-doped silicon dioxide (otherwise referred to as fluorinated silica glass (FSG)). A dielectric constant (k) of each of the dielectric layers 112 of the integrated circuit 100A, 100B may be smaller than a dielectric constant (k) of each of the dielectric layers 312 of the bridge die 300. An equivalent total dielectric constant (k) of the dielectric layers 112 of the integrated circuit 100A, 100B may be smaller than an equivalent total dielectric constant (k) of the dielectric layers 312 of the bridge die 300. For example, the dielectric layers 112 include ELK dielectric material while the dielectric layers 312 include low-k dielectric material or other dielectric material having a dielectric constant larger than 2.1. The dielectric layer 312 may be formed any acceptable deposition process, such as spin coating, CVD, laminating, the like, or a combination thereof.

The conductive patterns 314 may be conductive lines 314a and/or conductive vias 314b. The conductive vias 314b may extend through the dielectric layers 312 to provide vertical connections between layers of conductive lines 314a. The conductive pattern 314 may include copper, silver, gold, tungsten, aluminum, copper doped with aluminum or manganese, a combination thereof, or the like. In alternative embodiments, the conductive pattern 314 further includes an optional diffusion barrier layer and/or optional adhesion layer. A material of the diffusion barrier layer may include titanium, titanium nitride, titanium oxide, tantalum, tantalum nitride, titanium oxide, or other alternatives, and suitable materials for the conductive material.

The conductive patterns 314 may be formed by using a damascene process, including forming a dielectric material, forming a plurality of openings corresponding to the desired patterns of the conductive lines and the conductive vias, filling the openings with a conductive material and removing excess of the conductive material outside the openings. In some embodiments, the conductive patterns 314 are formed by a dual damascene process, and the conductive lines 314a and the respective conductive vias 314b are formed integrally. In alternative embodiments, the conductive patterns 314 are formed by a single damascene process or other suitable process, and the conductive lines 314a and the conductive vias 314b are formed separately. In some embodiments, the interconnect structure 310 may include six layers of conductive lines 314a and conductive vias 314b and three layers of dielectric layers 312. In alternative embodiments, the interconnect structure 310 include a different number of layers of conductive patterns 314 and a different number of layers of dielectric layers 312. A pitch of the interconnect structure 310 may range from 10 μm to 25 μm.

In some embodiments, the conductive pads 320 are disposed on an outermost surface of the interconnect structure 310. The conductive pads 320 may be aluminum pads or other suitable conductive pads. The conductive pads 320 are electrically connected to the interconnect structure 310. For example, the conductive pads 320 are respectively disposed on the conductive vias 314b of the interconnect structure 310. In some embodiments, the passivation layer 330 is disposed over the conductive pads 320 and has a plurality of openings to expose portions of the conductive pads 320. The passivation layer 330 may include an oxide such as silicon oxide, a nitride such as silicon nitride, or the like. The passivation layer 330 may be formed any acceptable deposition process, such as CVD, PVD, spin coating, laminating, the like, or a combination thereof. The passivation layer 330 is conformal to the conductive pads 320, for example. The passivation layer 330 may be a single layer or a multiple layered structure.

In some embodiments, the conductive connectors 340 are formed on and electrically connected to the conductive pads 320 through the openings of the passivation layer 330 respectively. The conductive connectors 340 may be electrically connected to each other through the conductive pads 320 and the interconnect structure 310. The conductive connectors 340 may be disposed in the openings of the passivation layer 330 and on the passivation layer 330. The conductive connectors 340 are also referred to as conductive terminals. In some embodiments, the conductive connectors 340 includes conductive pads or conductive pillars 342 with solder regions 344 disposed thereon. The conductive connectors 340 may be micro bumps. In some embodiments, the conductive pads or conductive pillars 342 may have substantially vertical sidewalls. In some embodiments, the conductive connectors 340 may include a conductive material such as solder, copper, aluminum, gold, nickel, silver, palladium, tin, the like, or a combination thereof. In alternative embodiments, the conductive connectors 340 may be ball grid array (BGA) connectors, solder balls, metal pillars, controlled collapse chip connection (C4) bumps, electroless nickel-electroless palladium-immersion gold technique (ENEPIG) formed bumps, or the like. The conductive connectors 340 may be formed by a suitable process such as evaporation, plating, ball drop, screen printing, or a ball mounting process. In alternative embodiments, a diffusion barrier layer (not shown) is disposed under a bottom surface of the conductive connector 340. A material of the diffusion barrier layer may include titanium, titanium nitride, titanium oxide, tantalum, tantalum nitride, titanium oxide, or other alternatives. In some embodiments, the conductive connectors 340 are arranged along a periphery of the bridge die 300. For example, the conductive connectors 340 are disposed at four sides of the bridge die 300. In alternative embodiments, the conductive connectors 340 are disposed at opposite sides of the bridge die 300. In some embodiments, as shown in FIG. 1D, the passivation layer 330 is a single layer and in direct contact with the conductive pad 320 and the conductive connector 340. In some embodiments, the passivation layer 330 is further in direct contact with the interconnect structure 310. For example, the passivation layer 330 is further in direct contact with the dielectric layer 312 of the interconnect structure 310.

In some embodiments, the bridge die 300 is bonded to the RDL structure 200 through the conductive connectors 340. For example, the solder regions 344 of the conductive connectors 340 are bonded to the outermost (e.g., topmost) conductive patterns 220 (e.g., conductive pads 222-4) of the RDL structure 200 using a flip chip bonding process. A reflow process may be applied to adhere the solder regions 344 of the conductive connectors 340 to the conductive patterns 220. In some embodiments, after the reflow process, the solder region 344 of the conductive connector 340 is rounded.

In some embodiments, after bonding the bridge die 300 to the RDL structure 200, an underfill 350 is formed to fill the space between the bridge die 300 and the RDL structure 200. The underfill 350 covers a surface of the passivation layer 330 (also a surface of the bridge die 300 facing the integrated circuits 100A, 100B), sidewalls of the conductive connectors 340, a surface of the dielectric layer 210 (also a surface of the integrated circuits 100A, 100B facing the bridge die 300) and sidewalls of the conductive patterns 220 (e.g., conductive pads 222-4). In some embodiments, the underfill 350 further extends upward to cover a portion of a sidewall of the bridge die 300. The underfill 350 may be a polymer such as epoxy or other suitable material.

The bridge die 300 provides electrical connection between devices directly bonded to the conductive connectors 340. For example, the bridge die 300 provides electrical connection between the integrated circuits 100A, 100B. In embodiments where the substrate 302 includes silicon, the bridge die 300 is also referred to as a silicon bus, a silicon bridge or a local silicon interconnect (LSI). In some embodiments, the RDL structure 200 is disposed between the bridge die 300 and the integrated circuits 100A, 100B. The bridge die 300 and the integrated circuits 100A, 100B are disposed at opposite sides of the RDL structure 200 along the first direction D1. For example, the bridge die 300 is disposed on a first surface of the RDL structure 200, and the integrated circuits 100A, 100B are disposed on a second surface opposite to the first surface of the RDL structure 200. The integrated circuits 100A, 100B may be electrically connected to each other through the bridge die 300 and the RDL structure 200 (e.g., routing structures 212A, 212B). In some embodiments, the bridge die 300 is bonded to the RDL structure 200 after the integrated circuits 100A, 100B are bonded to the RDL structure 200. Thus, in embodiments where the bridge die 300 is a local silicon interconnect (LSI) and the RDL structure 200 is an integrated fan-out structure, the manufacturing process of the semiconductor device is also referred to as InFO-LSI last process. However, the disclosure is not limited thereto. In alternative embodiments, the bridge die 300 may be bonded to the RDL structure 200 before the integrated circuits 100A, 100B are bonded to the RDL structure 200.

In some embodiments, a plurality of conductive connectors 240 are formed over the RDL structure 200. The conductive connectors 240 may be formed before or after the bridge die 300 is bonded to the RDL structure 200. The conductive connectors 240 are also referred to as conductive terminals. In some embodiments, the conductive connectors 240 are ball grid array (BGA) connectors. In alternative embodiments, the conductive connectors 240 are solder balls, metal pillars, controlled collapse chip connection (C4) bumps, micro bumps, electroless nickel-electroless palladium-immersion gold technique (ENEPIG) formed bumps, or the like. The conductive connectors 240 are electrically connected to the integrated circuits 100A, 100B through the RDL structure 200 (e.g., routing structures 214).

Referring to FIG. 1E, an integrated circuit 400 is bonded to the formed package structure. For example, the formed package structure of FIG. 1D is removed from the carrier C, and is flipped over and attached to another carrier (not shown). Then, the integrated circuit 400 are, for example, bonded to the through vias 150 through conductive connectors 410, and an underfill 420 is formed aside the conductive connectors 410. After that, the formed package structure is removed from the carrier, and a semiconductor device is formed. The integrated circuit 400 may have a structure similar to the integrated circuit 100A, 100B. The integrated circuit 400 may be a memory die such as a dynamic random access memory (DRAM) die or a static random access memory (SRAM) die. However, the disclosure is not limited thereto. The integrated circuit 400 may be other suitable die. In some embodiments, the underfill 420 further extends upward to cover a portion of a sidewall of the integrated circuit 400. The underfill 420 may be a polymer such as epoxy or other suitable material.

In some embodiments, the RDL structure 200 electrically connects the integrated circuits 100A, 100B, 400 and the bridge die 300. For example, the integrated circuits 100A, 100B are electrically connected to each other through the bridge die 300 and the routing structures 212A, 212B, and the integrated circuits 100A, 100B and 400 are electrically connected to each other through the routing structures 214 and the through vias 150.

In some embodiments, the passivation layer 130 including inorganic material (e.g., oxide or nitride) is in direct contact with the conductive pad 120, and thus the strain generated due to expansion and contraction of the conductive pad 120 may be released through and shared by the passivation layer 130. Accordingly, compared to the embodiments in which the conductive pad 120 is in direct contact with organic material such as polyimide, the conductive pad 120 may be prevented from being deformed and the conductive pattern 220 (e.g., conductive via 224-1) of the routing structure 212A, 212B may be prevented from cracking. For example, after performing the reliability torture with multiple thermal cycles such as reflowing processes between high temperature (e.g., higher than 260° C.) and low temperature, the conductive via 224-1 is prevented from cracking. Accordingly, the performance and the reliability of the semiconductor device may be improved.

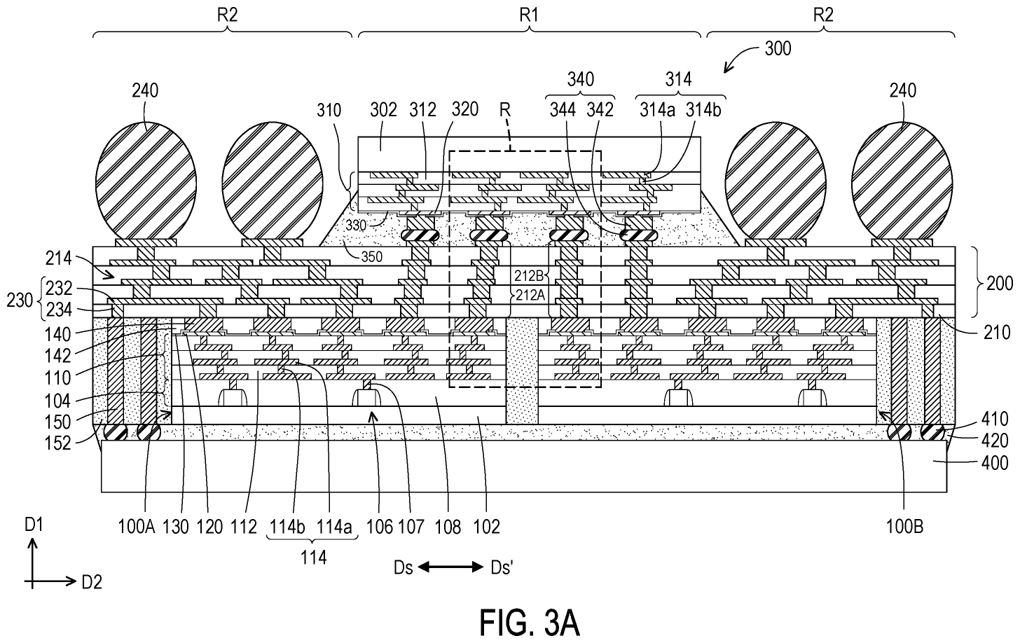

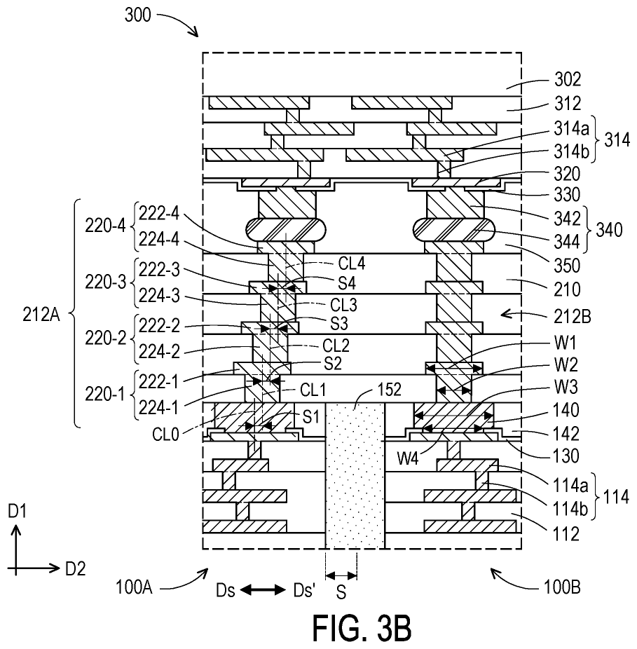

FIG. 3A is a schematic cross-sectional view of a semiconductor device according to some embodiments of the disclosure, and FIG. 3B is a partial enlarged view of a region R of FIG. 3A. The semiconductor device of FIG. 3A is similar to the semiconductor device of FIG. 1E, and the difference lies in the location of the integrated circuit 100A with respect to the bridge die 300 and the configuration of the routing structure 212A.

Referring to FIG. 3A and FIG. 3B, in some embodiments, compared to FIG. 1E, the integrated circuit 100A may be shifted with respect to the bridge die 300 along a direction Ds by a shift S. The shift S may be occurred during the placement of the integrated circuit 100A. In some embodiments, as shown in FIG. 3A and FIG. 3B, the conductive patterns 220 of the routing structure 212A are stacked on one another and the center lines CL1 to CL4 of the conductive patterns 220 are not aligned with one another. The center lines CL1-CL4 of the conductive patterns 220-1, 220-2, 220-3, 220-4 may be also not aligned with the center line CL0 of the conductive connector 140 of the integrated circuit 100A, 100B. For example, a shift S1-S4 is respectively formed between the center lines CL0-CL4 of adjacent two of the conductive connector 140 and the conductive patterns 220-1, 220-2, 220-3, 220-4. In some embodiments, the shift S1-S4 is substantially eqaul. However, the disclosure is not limited thereto. In alternative embodiments, the shift S1-S4 is different. In an embodiment, at least one of the shifts S1-S4 may be zero. In such embodiments, the adjacent two of the conductive connector 140 and the conductive patterns 220-1, 220-2, 220-3, 220-4 is not shifted with each other.

As shown in FIG. 3A and FIG. 3B, the conductive pattern 220-1 is partially overlapped with the conductive connector 140, the conductive pattern 220-2 is partially overlapped with the conductive connector 220-1, the conductive pattern 220-3 is partially overlapped with the conductive connector 220-2, and the conductive pattern 220-4 is partially overlapped with the conductive connector 220-3, for example. In some embodiments, a horizontal distance (along the second direction D2) between the conductive patterns 220-1, 220-2, 220-3, 220-4 and the conductive connector 140 becomes increased as a vertical distance (along the first direction D1) between the conductive patterns 220-1, 220-2, 220-3, 220-4 and the conductive connector 140 increases. In some embodiments, the routing structures 212A bonded to the integrated circuit 100A are both inclined towards the same direction Ds' while the routing structures 212B bonded to the integrated circuit 100B are not inclined. The direction Ds' is opposite to the direction Ds of the shift of the integrated circuit 100A, for example. In some embodiments, by using this configuration of the routing structures 212A between the integrated circuit 100A and the bridge die 300, the shift S of the integrated circuit 100A with respect to the bridge die 300 may be compensated. For example, a total of shifts S1-S4 is substantially equal to the shift S of the integrated circuit 100A with respect to the bridge die 300, that is, S=S1+S2+S3+S4. In some embodiments, since the shift is compensated by the arrangement of the conductive patterns of the routing structures, the performance and the reliability of the semiconductor device may be improved.

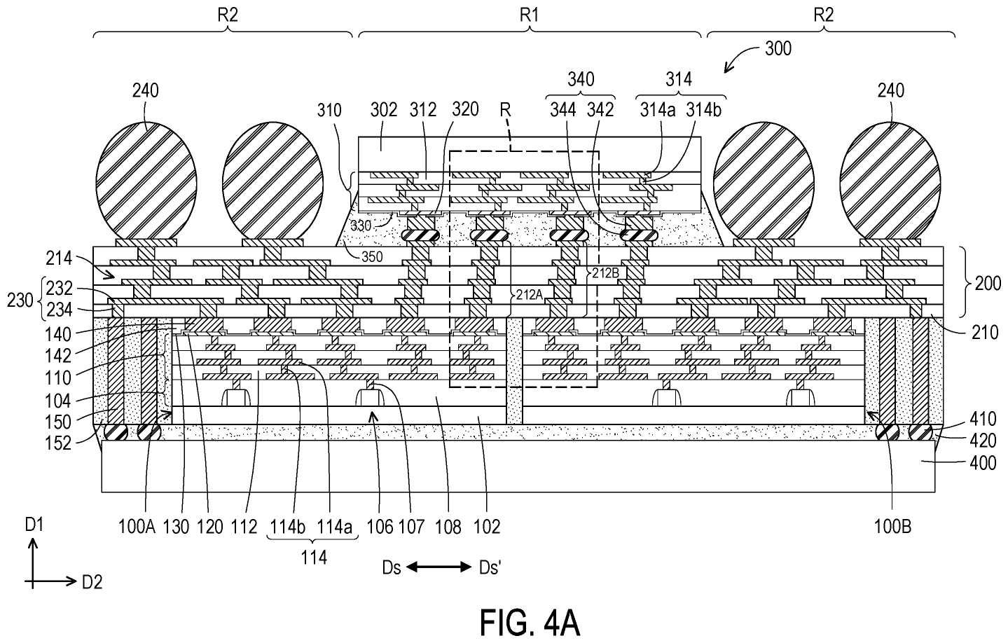

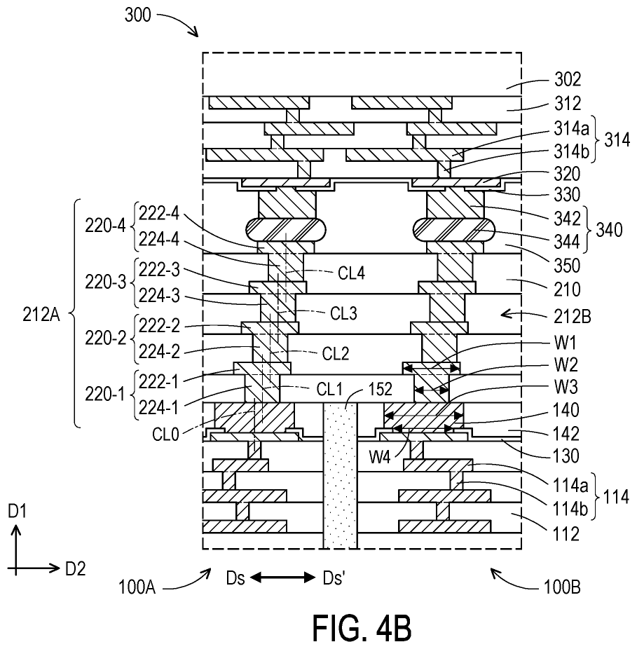

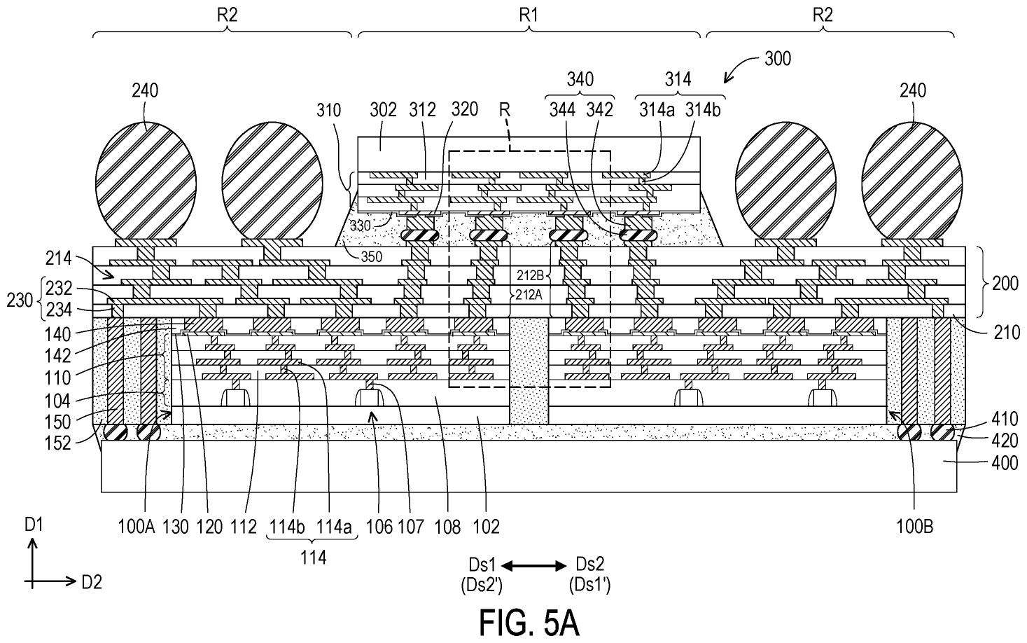

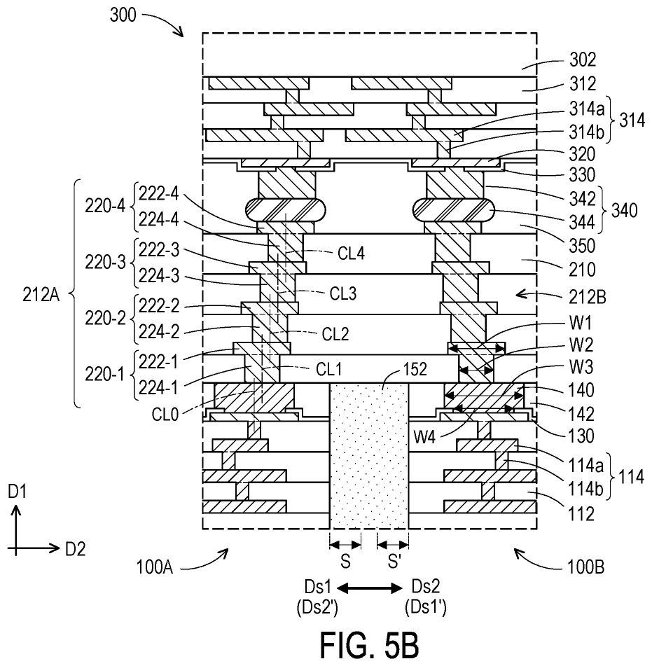

In alternative embodiments, as shown in FIG. 4A and FIG. 4B, when the integrated circuits 100A, 100B are both shifted with respect to the bridge die 300 along the same direction Ds, both routing structures 212A, 212B have the configuration similar to that of the routing structure 212A in FIG. 3A and FIG. 3B. In such embodiments, the routing structures 212A bonded to the integrated circuit 100A and the routing structures 212B bonded to the integrated circuit 100B are both inclined towards the direction Ds' opposite to the direction Ds. In alternative embodiments, as shown in FIG. 5A and FIG. 5B, when the integrated circuits 100A, 100B are shifted with respect to the bridge die 300 along opposite directions Ds1, Ds2, the routing structures 212A and the routing structures 212B are inclined towards opposite directions Ds1′, Ds2′. For example, the integrated circuit 100A is shifted with respect to the bridge die 300 along the direction Ds1 by a shift S, and the integrated circuit 100B is shifted with respect to the bridge die 300 along the direction Ds2 by a shift S′. The routing structures 212A bonded to the integrated circuit 100A are inclined towards the direction Ds1′, and the routing structures 212B bonded to the integrated circuit 100B are inclined towards the direction Ds2′. The direction Ds2 is opposite to the direction Ds1, the directions Ds1′ is opposite to the direction Ds1, and the directions Ds2′ is opposite to the direction Ds2. In some embodiments, since the shift is compensated by the arrangement of the conductive patterns of the routing structures, the performance and the reliability of the semiconductor device may be improved.

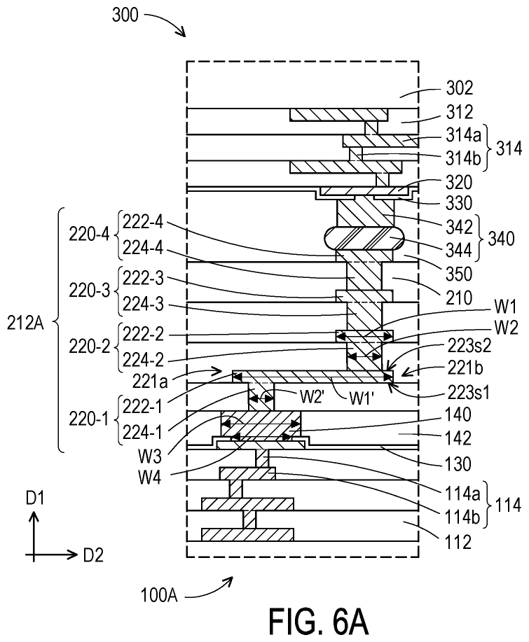

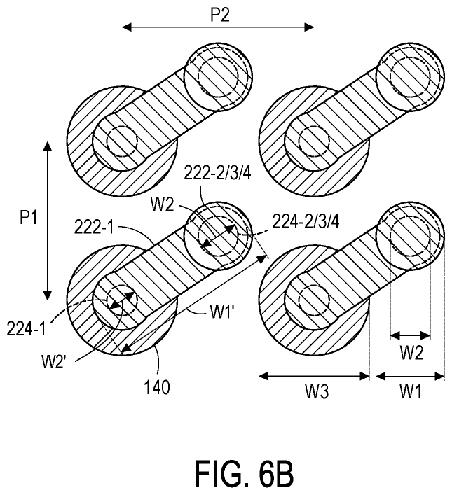

In the above embodiments, the conductive patterns 220 of the routing structures 212A are stacked directly on one another (e.g., FIG. 1E to 2B) or shifted with one another (e.g., FIG. 3A to FIG. 5B). However, the disclosure is not limited thereto. The routing structures 212A, 212B may have other configurations. In some embodiments, as shown in FIGS. 6A and 6B, in the routing structure 212A, the conductive pad 222-1 is disposed between the conductive via 224-1 and the conductive via 224-2. In some embodiments, the conductive via 224-1 is connected to an end 221a of a surface 223s1 of the conductive pad 222-1, and the conductive via 224-2 is connected to an end 221b of a surface 223s2 of the conductive pad 222-1. The end 221b is opposite to the end 221a. The surface 223s2 is opposite to the surface 223s1. For example, the surface 223s1 is a bottom surface and the surface 223s2 is a top surface. The width W1′ of the conductive pad 222-1 is larger than the width W1 of other conductive pads 222-2, 222-3, 222-4, for example. The width W1 of the conductive pads 222-2, 222-3, 222-4 may be the same or different. The width W2′ of the conductive via 224-1 may be smaller than the width W2 of the conductive vias 224-2, 224-3, 224-4. The width W2 of the conductive vias 224-2, 224-3, 224-4 may be substantially the same or different. A pitch P1 ranges from 20 μm to 30 μm, and a pitch P2 ranges from 15 μm to 25 μm, for example. In some embodiments, as shown in FIG. 6A, the conductive via 224-1 and the conductive via 224-2 are not overlapped along the first direction D1. That is, as shown in FIG. 6B, the conductive via 224-1 and the conductive via 224-2 are separated from each other. In such embodiments, the conductive via 224-1 and the conductive via 224-2 are not stacked in an overlap manner and also referred to as jogged vias.

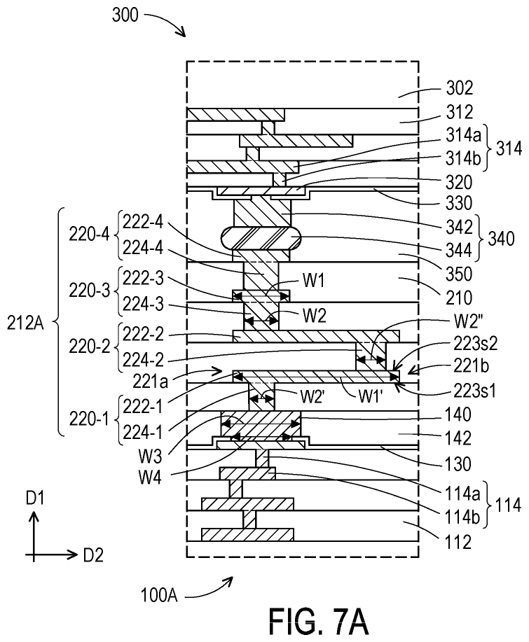

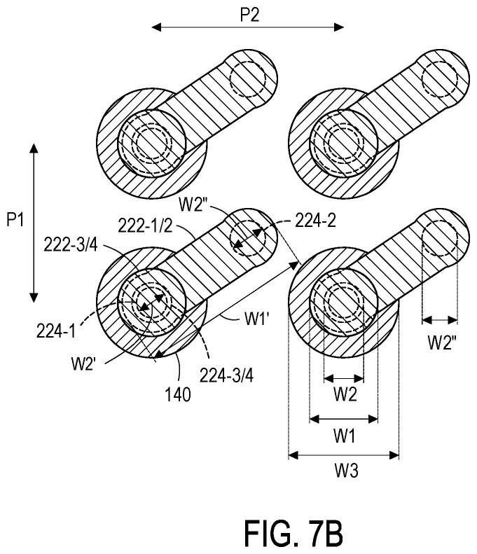

In some embodiments, as shown in FIGS. 7A and 7B, in the routing structure 212A, the conductive pad 222-1 is disposed between the conductive via 224-1 and the conductive via 224-2, and the conductive pad 222-2 is disposed between the conductive via 224-2 and the conductive via 224-3. In some embodiments, the conductive via 224-1 is connected to an end 221a of a surface 223s1 of the conductive pad 222-1, and the conductive via 224-2 is connected to an end 221b of a surface 223s2 of the conductive pad 222-1. Similarly, the conductive via 224-2 is connected to the end 221b of the surface 223s1 of the conductive pad 222-2, and the conductive via 224-3 is connected to the end 221a of the surface 223s2 of the conductive pad 222-2. The end 221b is opposite to the end 221a. The surface 223s2 is opposite to the surface 223s. For example, the surface 223s1 is a bottom surface and the surface 223s2 is a top surface. The width W1′ of the conductive pads 222-1, 222-2 is larger than the width W1 of other conductive pads 222-3, 222-4. The width W1′ of the conductive pads 222-1, 222-2 may be the same or different, and the width W1 of other conductive pads 222-3, 222-4 may be the same or different. The width W2′ of the conductive via 224-1 may be smaller than the width W2″ of the conductive via 224-2, and the width W2″ of the conductive via 224-2 may be smaller than the width W2 of the conductive vias 224-3, 224-4. The width W2 of the conductive vias 224-3, 224-4 may be substantially the same or different. A pitch P1 ranges from 20 μm to 30 μm, and a pitch P2 ranges from 15 μm to 25 μm, for example. In some embodiments, as shown in FIGS. 7A and 7B, along the first direction D1, the adjacent conductive vias 224-1, 224-2 are not overlapped, the adjacent conductive vias 224-2, 224-3 are not overlapped, and the adjacent conductive vias 224-1 and 224-3 are overlapped. In other words, the conductive vias 224-1 to 224-4 are not entirely stacked in an overlap manner. In such embodiments, the routing structure 212A, 212B has a U-turn portion (e.g., formed by the adjacent conductive pads 222-1, 222-2 and the conductive via 224-2 therebetween).

In above embodiments, the integrated circuit 400 is disposed above the package structure including the integrated circuits 100A, 100B and the bridge die 300. However, the disclosure is not limited thereto. In alternative embodiments, the package structure of FIG. 1D including the integrated circuits 100A, 100B and the bridge die 300 may be removed from the carrier C and then integrated with other devices, to form a suitable configuration with desired function. For example, as shown in FIG. 8, the package structure including the integrated circuits 100A, 100B and the bridge die 300 is integrated with integrated circuits 400 over a circuit substrate 500. For example, the package structure is bonded to the circuit substrate 500 through the conductive connectors 240. The integrated circuits 400 may be DRAM, and the circuit substrate 500 may include conductive connectors 510 at the outermost surface and a plurality of conductive features (e.g., conductive lines and/or vias) disposed in the circuit substrate 500 and connected to each other. In some embodiments, an underfill 502 is formed to fill the space between the package structure and the circuit substrate 500, and an underfill 504 is formed to fill the space between the integrated circuit 400 and the circuit substrate 500. In some embodiments, a heat dissipation element 600 may be further disposed on the circuit substrate 500 to cover the package structure and/or the integrated circuits 400, so as to enhance heat dissipation. The heat dissipation element 600 may be a conductive lid or a heatsink device.

In accordance with some embodiments of the disclosure, a semiconductor device includes a first integrated circuit, a bridge die, and a redistribution layer (RDL) structure. The first integrated circuit includes a first interconnect structure, a first passivation layer and a first conductive connector electrically connected to the first interconnect structure and disposed on the first passivation layer. The bridge die bridge die includes a second interconnect structure, a second passivation layer and a second conductive connector electrically connected to the second interconnect structure. The RDL structure is disposed between and electrically connected to the first integrated circuit and the bridge die, wherein the first passivation layer is in direct contact with the first conductive connector, the first conductive connector is in direct contact with the RDL structure, and the first passivation layer is a single layer and includes a first inorganic material.

In accordance with some embodiments of the disclosure, a semiconductor device includes a first integrated circuit, a bridge die, and a RDL structure. The first integrated circuit includes a first active device, a first conductive pad, a first passivation layer, a first conductive connector on the first passivation layer, and a first dielectric layer surrounding the first conductive connector. The bridge die is free of active devices and electrically connected to the first integrated circuit. The RDL structure is disposed between and electrically connected to the first integrated circuit and the bridge die. The RDL structure includes a plurality of second dielectric layers and a plurality of conductive patterns in the second dielectric layers. The first passivation layer is in direct contact with the first conductive pad and the first dielectric layer, the first dielectric layer is in direct contact with one of the second dielectric layers, and a hardness of the first passivation layer is larger than a hardness of the first dielectric layer.

In accordance with some embodiments of the disclosure, a semiconductor device includes a first integrated circuit, a second integrated circuit, a bridge die, and a RDL structure. The first integrated circuit includes a first conductive pad, a first passivation layer covering the first conductive pad, a first conductive connector disposed on the first passivation layer and a first dielectric layer surrounding the first conductive connector. The first passivation layer is a single layer and an inorganic layer, and the first passivation layer is in direct contact with the first conductive pad, the first conductive connector and the first dielectric layer. The bridge die is free of active devices and includes a second conductive connector. The RDL structure is disposed between the first integrated circuit and the bridge die and between the second integrated circuit and the bridge die. The RDL includes a plurality of conductive patterns stacked between the first conductive connector and the second conductive connector, wherein the bridge die electrically connects the first integrated circuit and the second integrated circuit through the conductive patterns.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first integrated circuit, comprising a first interconnect structure, a first passivation layer and a first conductive connector electrically connected to the first interconnect structure and disposed on the first passivation layer;
a bridge die, comprising a second interconnect structure, a second passivation layer and a second conductive connector electrically connected to the second interconnect structure; and
a redistribution layer (RDL) structure, disposed between and electrically connected to the first integrated circuit and the bridge die, wherein the first passivation layer is in direct contact with the first conductive connector, the first conductive connector is in direct contact with the RDL structure, and the first passivation layer is a single layer and includes a first inorganic material.

2. The semiconductor device according to claim 1, wherein the first integrated circuit comprises an active device, and the bridge die is free of active devices.

3. The semiconductor device according to claim 1, wherein the first interconnect structure comprises a plurality of first dielectric layers, the second interconnect structure comprises a plurality of second dielectric layers, and a dielectric constant of each of the first dielectric layers is lower than a dielectric constant of each of the second dielectric layers.

4. The semiconductor device according to claim 1, wherein the second passivation layer is in direct contact with the second conductive connector, the second conductive connector is in direct contact with the RDL structure, and the second passivation layer is a single layer and includes a second inorganic material.

5. The semiconductor device according to claim 1, wherein the RDL structure comprises a plurality of first conductive patterns stacked and overlapped with one another along a stacking direction of the first integrated circuit and the bridge die.

6. The semiconductor device according to claim 1, wherein the first inorganic material of the first passivation layer comprises silicon oxide, silicon nitride or a combination thereof.

7. A semiconductor device, comprising:
a first integrated circuit, comprising a first active device, a first conductive pad, a first passivation layer, a first conductive connector on the first passivation layer, and a first dielectric layer surrounding the first conductive connector;
a bridge die free of active devices, electrically connected to the first integrated circuit; and
a RDL structure, disposed between and electrically connected to the first integrated circuit and the bridge die, the RDL structure comprising a plurality of second dielectric layers and a plurality of conductive patterns in the second dielectric layers, wherein the first passivation layer is in direct contact with the first conductive pad and the first dielectric layer, the first dielectric layer is in direct contact with one of the second dielectric layers, and a hardness of the first passivation layer is larger than a hardness of the first dielectric layer.

8. The semiconductor device according to claim 7, wherein the first passivation layer is a single layer and an inorganic layer.

9. The semiconductor device according to claim 7, wherein a material of the first passivation layer comprises silicon oxide, silicon nitride or a combination thereof.

10. The semiconductor device according to claim 7, wherein the first passivation layer is in direct contact with the first conductive connector, and the first conductive connector is in direct contact with one of the conductive patterns.

11. The semiconductor device according to claim 7, wherein a surface of the first dielectric layer facing the RDL structure is substantially coplanar with a surface of the first conductive connector.

12. The semiconductor device according to claim 7, wherein the hardness of the first passivation layer is larger than a hardness of the one of the second dielectric layers.

13. A semiconductor device, comprising:
a first integrated circuit, comprising a first conductive pad, a first passivation layer covering the first conductive pad, a first conductive connector disposed on the first passivation layer and a first dielectric layer surrounding the first conductive connector, wherein the first passivation layer is a single layer and an inorganic layer, and the first passivation layer is in direct contact with the first conductive pad, the first conductive connector and the first dielectric layer;
a second integrated circuit;
a bridge die free of active devices, comprising a second conductive connector; and
a RDL structure between the first integrated circuit and the bridge die and between the second integrated circuit and the bridge die, the RDL comprising a plurality of conductive patterns stacked between the first conductive connector and the second conductive connector, wherein the bridge die electrically connects the first integrated circuit and the second integrated circuit through the conductive patterns.

14. The semiconductor device according to claim 13, wherein a material of the first passivation layer comprises silicon oxide, silicon nitride or a combination thereof.

15. The semiconductor device according to claim 13, wherein the conductive patterns are stacked along a first direction along which the first integrated circuit, the RDL structure and the bridge die are stacked.

16. The semiconductor device according to claim 15, wherein the conductive patterns comprise a plurality of conductive pads and a plurality of conductive vias, and the conductive pads and the conductive vias are alternately stacked and overlapped with one another along the first direction.

17. The semiconductor device according to claim 13, wherein horizontal distances between the first conductive connector and the conductive patterns become increased as vertical distances between the first conductive connector and the conductive patterns increase.

18. The semiconductor device according to claim 13, wherein the conductive patterns comprise a first conductive via, a first conductive pad and a second conductive via, the first conductive via is physically connected to a first end of a first surface of the first conductive pad, the second conductive via is physically connected to a second end of a second surface of the first conductive pad, the first end is opposite to the second end, and the first surface is opposite to the second surface.

19. The semiconductor device according to claim 18, wherein the conductive patterns further comprise a third conductive via on the first conductive via, the first conductive pad and the second conductive via, and the third conductive via and the second conductive via are overlapped along a first direction along which the first integrated circuit, the RDL structure and the bridge die are stacked.

20. The semiconductor device according to claim 18, wherein the conductive patterns further comprise a third conductive via on the first conductive via, the first conductive pad and the second conductive via, and the third conductive via and the second conductive via are not overlapped along a first direction along which the first integrated circuit, the RDL structure and the bridge die are stacked.
